(19) United States
(12) Patent Application Publication
(10) Pub. No.: US 2014/0125342 A1
(43) Pub. Date: May 8, 2014

(54) Magnet configuration with a superconducting magnet coil system and a magnetic field forming device for magnetic resonance spectroscopy

(71) Applicant: BRUKER BIOSPIN AG, Faellanden (CH)

(72) Inventors: Pierre-Alain Bovier, Zuerich (CH); Guenter Kuebler, Zollikerberg (CH)

(21) Appl. No.: 14/052,707

(22) Filed: Oct. 12, 2013

(30) Foreign Application Priority Data
Nov. 5, 2012 (DE) 10 2012 220 126.2

(51) Int. Cl. G01R 33/3815; G01R 33/38

(52) U.S. Cl. CPC G01R 33/3815; G01R 33/3802
USPC 324/322; 324/228; 29/599

(57) ABSTRACT

A magnet assembly has a field shaping device (P1) that is cylindrically symmetric with respect to the z-axis and made of magnetic material. At least parts of the field shaping device have a radial distance from the z-axis of less than 80 millimeters and compensate for at least one of the inhomogeneous field parts Aₙ₀·zⁿ of the magnet coil system. The field shaping device has one or more non cylindrically symmetric recesses, which are constituted such that at least a coefficient Aₙₘ or Bₙₘ in the magnetic field expansion of the magnet assembly according to the spherical harmonic functions is reduced by at least 50%. In this way, the field homogeneity of the working volume can be substantially increased in a simple manner and without increasing the volume of the magnet assembly, wherein only a few iterations are required to optimize the magnet assembly.

This application claims Paris convention priority of DE 10 2012 220 126.2 filed Nov. 5, 2012 the entire disclosure of which is hereby incorporated by reference.

### BACKGROUND OF THE INVENTION

The invention concerns a magnet assembly for use in an apparatus for magnetic resonance spectroscopy with a superconducting magnet coil system for producing a magnetic field in the direction of a z-axis in a working volume disposed on the z-axis about z=0, wherein the field of the magnet coil system in the working volume has at least one inhomogeneous part Aₙ₀·zⁿ, where n≧2, whose contribution to the total field strength on the z-axis about z=0 varies with the nth power of z, and wherein a field shaping device that is cylindrically symmetric with respect to the z-axis made of magnetic material is provided, which at least in parts has a radial distance from the z-axis of less than 80 millimeters and compensates for at least one of the inhomogeneous field parts Aₙ₀·zⁿ of the magnet coil system by at least fifty percent.

Such an assembly is known from U.S. Pat. No. 6,617,853 B2.

Superconducting magnets are used in various fields of application. These include, in particular, spectroscopic magnetic resonance methods. To achieve good spectral resolution with such methods, the magnetic field must exhibit good homogeneity in the sample volume. The basic homogeneity of the superconducting magnet can be optimized with the geometric configuration of field-producing magnet coils. Typically, gaps must be provided (so-called notch structures) in which no wire is wound. This results in the loss of valuable space for magnet windings, which makes the magnets more expensive and enlarges the fringe field.

In an assembly according to U.S. Pat. No. 6,617,853 B2, a superconducting magnet for high resolution spectroscopy is designed more compactly by providing one or more magnetic rings, which perform the role of certain notch structures in the magnetic coils.

The z-component of the magnetic field of an assembly according to U.S. Pat. No. 6,617,853 B2 can be expanded in the sample volume according to the spherical harmonic functions:

$${B}_{z} ( r , z , ϕ ) = {\sum }_{n = 0}^{∞} {\sum }_{m = 0}^{n} {P}_{n}^{m} ( \frac{z}{\sqrt{{r}^{2} + {z}^{2}}} ) {( {r}^{2} + {z}^{2} )}^{n / 2} ( {A}_{nm} cos ( m ϕ ) + {B}_{nm} sin ( m ϕ ) ) ,$$

wherein according to the design, the coefficients Aₙₘ, where m≠0, and all coefficients Bₙₘ vanish. Based on the production tolerances in the magnet assembly, the coefficients Aₙₘ and Bₙₘ deviate from the calculated value. Shim coils are usually provided to correct for these non-vanishing coefficients, which can be powered with a dedicated power supply. For large deviations of the coefficients from their setpoint, the current required in certain shim coils may be too high and the magnetic field of the magnet assembly cannot be corrected as desired. Alternately, it might not be possible to correct for a problematic coefficient in the expansion of the magnetic field according to the spherical harmonic functions because no corresponding shim coil is provided. In such a situation, an expensive repair of the magnet system is required in which part of the magnet assembly has to be replaced.

The object of this invention is therefore, in a magnet assembly of the type defined above, to substantially increase the field homogeneity in the working volume by simple technical measures and without increasing the volume of the magnet assembly, wherein as few iterations as possible are to be required to optimize the magnet assembly.

### SUMMARY OF THE INVENTION

This object is achieved in a manner that is as surprisingly simple as effective with a magnet assembly of the type stated above, which is characterized in that, in the field shaping device, one or more non cylindrically symmetric recesses are provided, which are constituted such that at least one coefficient Aₙₘ or Bₙₘ, where m≠0, is reduced in the magnetic field expansion of the magnet assembly according to the spherical harmonic functions

$${B}_{z} ( r , z , ϕ ) = {\sum }_{n = 0}^{∞} {\sum }_{m = 0}^{n} {P}_{n}^{m} ( \frac{z}{\sqrt{{r}^{2} + {z}^{2}}} ) {( {r}^{2} + {z}^{2} )}^{n / 2} ( {A}_{nm} cos ( m ϕ ) + {B}_{nm} sin ( m ϕ ) )$$

by an amount of at least fifty percent.

By the geometric arrangement of the recesses, certain coefficients Aₙₘ or Bₙₘ, where m≠0, can be changed in a targeted manner in the magnetic field expansion according to the spherical harmonic functions of the magnet assembly.

One considerable advantage of recesses in a cylindrically symmetric field shaping device made of magnetic material is the possibility of improving the field homogeneity of the magnet assembly in the working volume without additional material. In principle, the objective of improved field homogeneity could also be achieved with additional magnetic material, which would be glued, for example, onto the field device. However, this could only be achieved if space for such field corrections were provided from the outset, which would enlarge the magnet assembly and render it more expensive.

Specially preferred embodiments of the inventive magnet assembly are characterized in that the field shaping device comprises cooled components, in particular, such that have the temperature of the liquid-helium bath, which cools the magnet coil system. The advantage of the low temperature is better magnetic properties of the magnetic material, that is, greater magnetization for a given external field. At a stable temperature, fluctuations of the magnetization are also suppressed, which ensures better stability of the homogeneity of the magnet assembly over time. The homogeneity of the magnet assembly also becomes substantially more stable because the relative position of the cooled components of the field shaping device with respect to the magnet coil system is not influenced by atmospheric conditions, that is, pressure and temperature. Components of the field shaping device that are at room temperature are namely typically mechanically connected to the magnet coil system via a long path. This path is deformed by temperature and pressure fluctuations in the laboratory to the extent that the relative position of these components of the field shaping device with respect to the magnet coil system is variable over time. The variable position results in a time dependence of the coefficients of the magnetic field expansion of the magnet assembly according to the spherical harmonic functions.

In a further embodiment, the magnet assembly is characterized in that the field shaping device comprises components that are mounted in a region of the magnet assembly, which is at room temperature. These components are easily accessible while in the operating condition and can be modified without raising the temperature of the magnet coil system.

An embodiment is especially advantageous, in which the magnet coil system has active shielding. This active shielding reduces the fringe field of the magnet assembly such that more space is available in the laboratory for other applications.

A further preferred embodiment is characterized in that at least part of the field shaping device is disposed radially within the innermost wire turn of the magnet coil system. When close to the z-axis, the efficiency of the field shaping device for compensating for the inhomogeneous field parts Aₙ₀·zⁿ of the magnet coil system is especially great.

An embodiment of the inventive magnet assembly is also advantageous, in which the field shaping device is magnetically completely saturated and is purely axially magnetized (in one direction along the z-axis). In this situation, calculation of the field produced by the field shaping device is especially simple and precise.

In a further advantageous embodiment, the field shaping device comprises components made of soft iron. Soft iron has the advantages of great permeability and high saturation induction. With these properties, the field shaping device is capable of high magnetization so that high field efficiency is achieved with little material.

An embodiment of the inventive magnet assembly is also advantageous in which parts of the field shaping device are subjected to surface treatment, in particular, have been galvanized. This surface treatment provides optimum protection against corrosion, which is indispensable, in particular, for parts made of soft iron.

An especially preferred embodiment of the inventive magnet assembly is characterized in that the field shaping device consists of a single element made of magnetic material. This is the simplest possible embodiment for the field shaping device with regard to production and assembly.

An embodiment of the inventive magnet assembly is also advantageous, in which the field shaping device comprises multiple elements made of magnetic material. This provides more degrees of freedom for optimization of the field shaping device.

In a further advantageous embodiment of the inventive magnet assembly, the field shaping device comprises magnetic foils, which are mounted on a carrier device. Especially close to the z-axis, the efficiency of magnetic material is so great that little material is required to produce the desired field shape. Foils therefore provide an ideal solution, in particular in view of the fact that they exhibit little variation in thickness.

In a further especially preferred embodiment of the inventive magnet assembly, at least a part of the non cylindrically symmetric recesses has through-holes through the field shaping device. Such through-holes are technically simple to implement, e.g. they can be cut out with laser beams.

Alternative embodiments are characterized in that at least a part of the non cylindrically symmetric recesses does not have through-holes through the field shaping device. Such non-through-holes have the advantage of providing more freedom for designing the field correction. A further advantage arises because the mechanical structure of the field shaping device is less weakened than by through-holes, especially, if the holes extend over a large angular range.

In advantageous variants of these embodiments, at least a part of the non cylindrically symmetric recesses is disposed on the inner side of the field shaping device. Alternatively or additionally in other variants, at least a part of the non cylindrically symmetric recesses can be disposed on the outer side of the field shaping device. Depending on the mechanical production method used, it may be advantageous to remove material from the inner or outer side of the field shaping device. With a mandrel for mechanical support on the inner side of the field shaping device, recesses can be made on the outer side using a grinding or milling method. Spark erosion can be implemented more simply on the inner side because the electrode is simpler to fabricate (usually in the shape of a “pie wedge”).

The scope of this invention includes a method for producing a magnet assembly of the inventive type described above, which is characterized in that at least a part of the non cylindrically symmetric recesses is cut by spark erosion. With spark erosion, high mechanical precision can be achieved.

Alternatively, in another variant of the method, at least a part of the non cylindrically symmetric recesses can be cut by a caustic substance. By suitable masking of parts of the field shaping device that do not have to be reworked; material can be simply removed by an etching method in an acid bath. The etching time must be set such that the correct material thickness is removed.

A further alternative is a variant of the method in which at least a part of the non cylindrically symmetric recesses is removed by electrolysis. Instead of an acid bath as in the method variant stated above, an electrolyte bath is used in this case.

Finally, in a further method variant, at least a part of the non cylindrically symmetric recesses is also removed by grinding or milling. Grinding and milling are age-old methods that any precision machinist is able to perform. Moreover, no special equipment is required to perform these processes.

In embodiments of the inventive magnet assembly that have non cylindrically symmetric recesses in the form of through-holes through the field shaping device, the holes can also be cut out with a laser beam. An essential advantage of the laser method is the very high mechanical precision, enabling even complicated shapes to be produced with the utmost precision.

The scope of this invention further includes a method for dimensioning the non cylindrically symmetric recesses in a magnet assembly of the inventive type described above, which is characterized in that the coefficients Aₙₘ and Bₙₘ of the magnetic field expansion are determined according to the spherical harmonic functions by means of a field measurement in or around the working volume in a magnet assembly with a field shaping device without non cylindrically symmetric recesses. By this method, those coefficients Aₙₘ and Bₙₘ can be determined that have to be corrected. A suitable geometry of the recesses for correcting these coefficients is determined by numerical methods.

Further advantages can be extracted from the description and the drawing. Moreover, the features stated above and further below can be used singly or together in any combination. The embodiments shown and described are not intended to be an exhaustive list but are rather examples to explain the invention.

The invention is shown in the drawing and is explained in more detail using the example of the embodiments. The figures show:

### BRIEF DESCRIPTION OF THE DRAWING

FIG. 1 a schematic vertical section through a radial half of the inventive magnet assembly;

FIG. 2 a schematic spatial representation obliquely viewed from above onto an embodiment of the inventive field shaping device with non cylindrically symmetric recesses, which are disposed on the inner and outer sides of the field shaping device;

FIG. 3 an embodiment in which the recesses constitute through-holes in the field shaping device;

FIG. 4 a schematic unfolded representation of the field shaping device that is shown in FIG. 3;

FIG. 5 an embodiment in which the recesses do not constitute through-holes but are disposed on the outer side of the field shaping device; and

FIG. 6 a schematic unfolded representation of the field shaping device shown in FIG. 5.

### DESCRIPTION OF THE PREFERRED EMBODIMENT

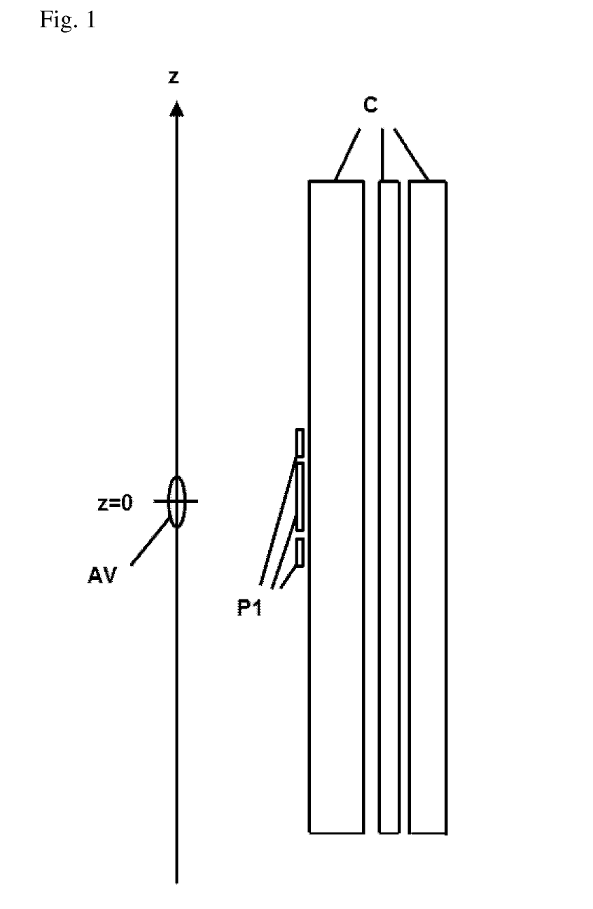

Based on FIG. 1, an embodiment of the inventive magnet assembly is shown that comprises a magnet coil system C and a magnetic field shaping device P1. At least part of the field shaping device P1 is typically located nearer to the z-axis than is the magnet coil system C. In this case, it consists of 3 rings. A working volume AV is disposed on the z-axis about z=0.

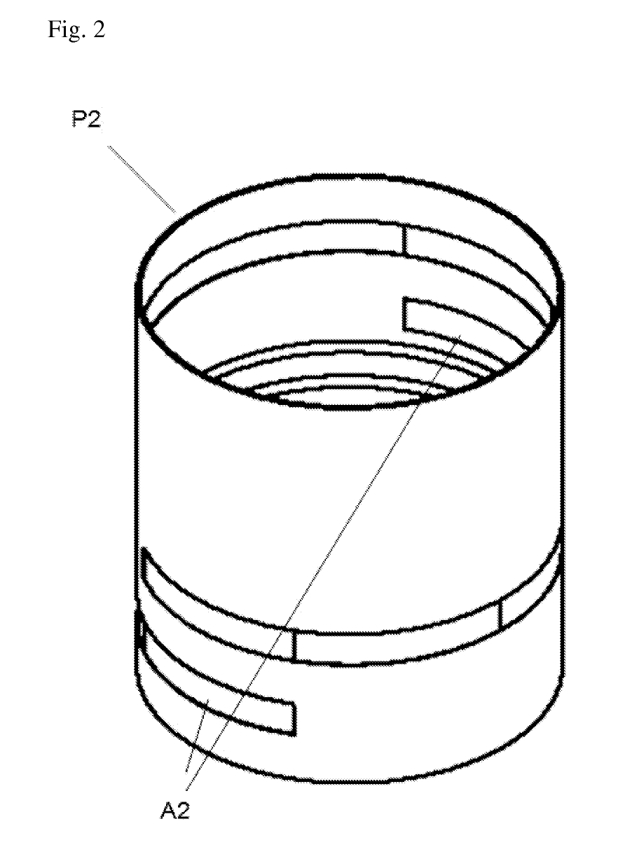

FIG. 2 shows an inventive field shaping device that typically exhibits non cylindrically symmetric recesses A2 on the inner and outer sides of the field shaping device. These recesses can in principle have shapes and depths of any degree of complication. In practice, however, simple shapes are preferred because the influence of the recesses on the field profile of the magnet assembly is then easier to calculate.

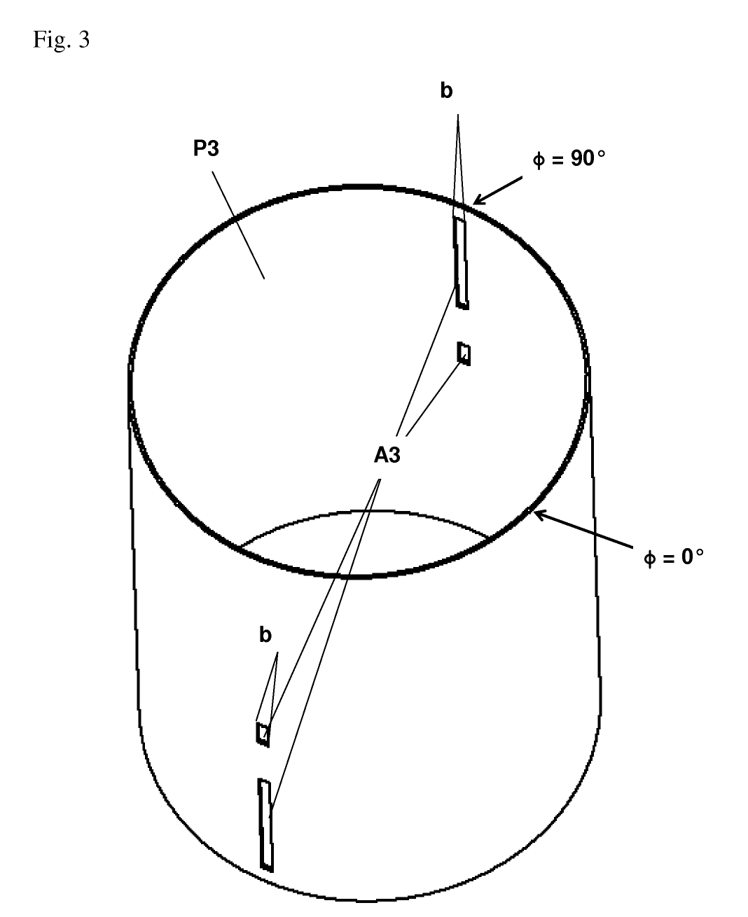

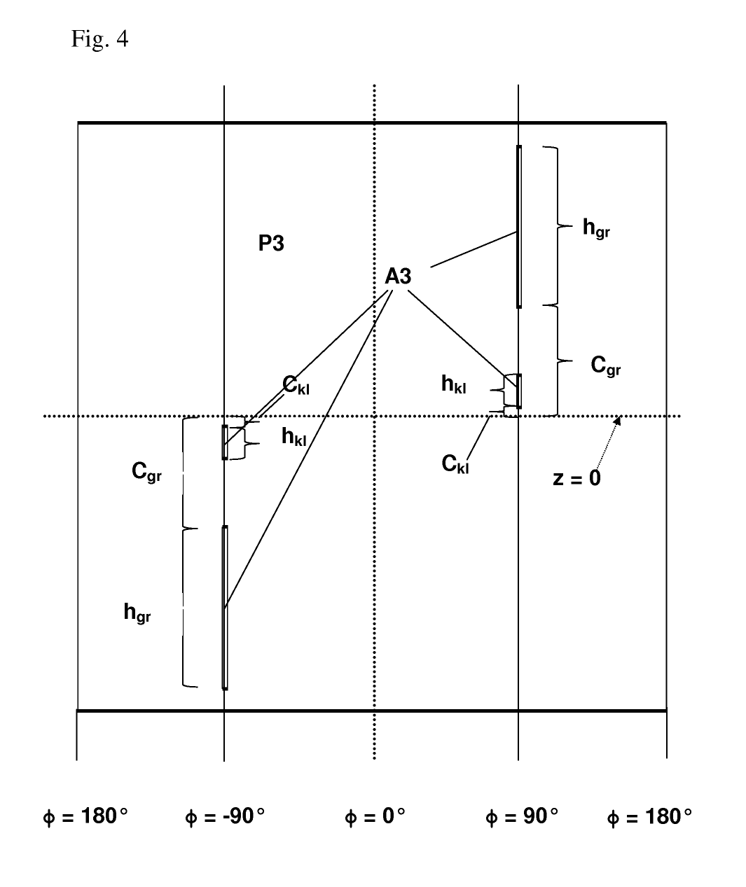

FIG. 3 shows an inventive field shaping device with through recesses for targeted changing of the B₂₁ coefficients in the magnetic field expansion of the magnet assembly according to the spherical harmonic functions. FIG. 4 shows a schematic unfolded view of this field shaping device with dimensions.

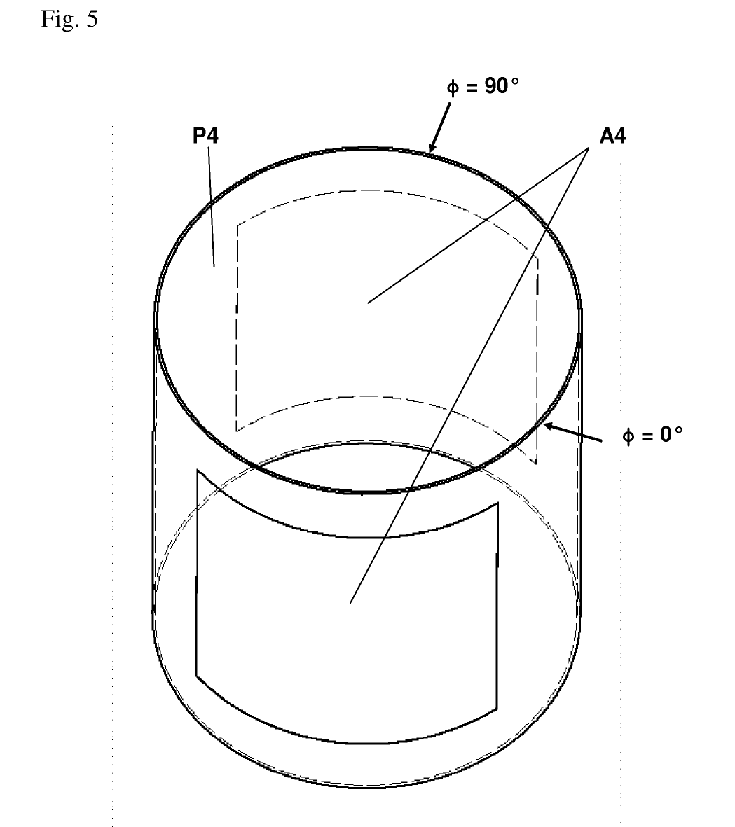

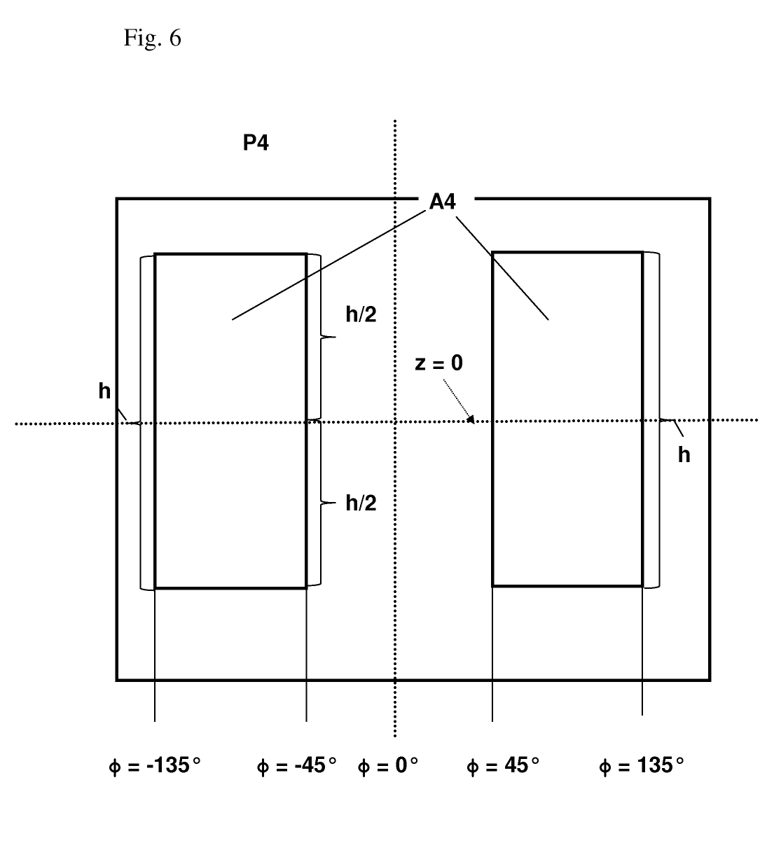

FIG. 5 shows an inventive field shaping device with recesses on the outer side of the field shaping device for targeted changing of the B₂₂ coefficients in the magnetic field expansion of the magnet assembly according to the spherical harmonic functions. FIG. 6 shows a schematic unfolded view of this field shaping device with dimensions.

Two embodiments are now described in detail in order to illustrate the invention. Both examples are based on the same cylindrically symmetric field shaping device, which consists of magnetic steel with saturation magnetization of 1.71*10⁶ A/m. Because the superconducting magnet produces a very high axial field at the position of the field shaping device, it is assumed that the total field shaping device is in magnetic saturation and that the magnetization is purely axial, that is, in the z-direction. The field shaping device can be characterized geometrically by its height of 800 mm, its wall thickness of 0.5 mm, and its internal diameter of 70 mm. It is symmetric with respect to the plane z=0. From this data, the following contributions of the field shaping device can be included in the coefficients of the magnetic field expansion of the magnet assembly according to the spherical harmonic functions:

A₀₀=−100 Gauss

A₂₀=0.98 Gauss/cm²

A₄₀=0.34 Gauss/cm⁴

All other coefficients are negligible. The contribution to the coefficient A₀₀ is irrelevant considering that the superconducting magnet produces several Tesla. The positive contributions to the coefficients A₂₀ and A₄₀ are especially interesting. They permit a coil design, which produces a negative A₂₀ of −0.98 Gauss/cm² and a negative A₄₀ of −0.34 Gauss/cm⁴. This results in compact coil assemblies with fewer notch structures than those that would have to produce an A₂₀ of 0 and an A₄₀ of 0. Ideally, the notch structures can even be omitted altogether.

Typically, in the test of the magnet assembly with the cylindrically symmetric field shaping device described above, a field profile in or around the working volume is measured. From this, by numeric procedure, the real coefficients Aₙₘ and Bₙₘ of the magnetic field expansion of the magnet assembly can be determined according to the spherical harmonic functions. If any of these coefficients are too large, they cannot be reduced to zero in the shimming procedure so that repair of the magnet assembly is necessary. Using two examples, it is demonstrated here how an excessive B₂₁ coefficient or an excessive B₂₂ coefficient can be corrected by means of recesses in the field shaping device.

The first example is shown in FIG. 3. FIG. 4 shows a schematic unfolded view in which φ=0° corresponds to the x-axis. In this case, the recesses are through-holes through the field shaping device. These holes are disposed symmetrically about the plane z=0, but offset by 180°. They all have a width b of 1.85 mm, which corresponds to an aperture angle of 3°. The small hole starts with a z-value Cₖₗ of 1.25 mm and has an axial extent hₖₗ of 4.5 mm. The large hole starts with a z-value C_{gr} of 15 mm and has an axial extent h_{gr} of 22 mm. In the positive z-range, the holes are disposed at an average angle of φ=90°, in the negative z-range at an average angle of φ=−90°. The contribution of the recesses to the coefficients Aₙₘ and Bₙₘ of the magnetic field expansion of the magnet assembly according to the spherical harmonic functions can be determined numerically. The most important non-vanishing coefficients are:

B₂₁=−0.18 Gauss/cm²

A₂₀=0.07 Gauss/cm²

A₂₂=0.04 Gauss/cm²

The latter two coefficients can be corrected by adaptation of the shimming currents. The first coefficient can compensate for a similarly large contribution from the magnet assembly.

The second example is shown in FIG. 5. FIG. 6 shows a schematic unfolded view in which φ=0° corresponds to the x-axis. In this case, the recesses are 0.07 mm deep structures in the field shaping device. They can be disposed on the inner or on the outer side of the field shaping device, depending on the production method. Both recesses are disposed symmetrically about the plane z=0 and are mutually offset by 180° in the circumferential direction. They have an aperture angle of 90° and an axial height of h=56 mm. The contribution of the recesses to the coefficients Aₙₘ and Bₙₘ of the magnetic field expansion of the magnet assembly according to the spherical harmonic functions can be determined numerically. The most important non-vanishing coefficients are:

A₂₂=−0.58 Gauss/cm²

A₂₀=−0.64 Gauss/cm²

The first coefficient can compensate for a similarly large contribution from the magnet assembly. The second coefficient can be corrected by adaptation of the corresponding shim current. If the shim is too weak for this, additional depressions can be provided in the field shaping device, which correct for this coefficient. However, unlike the recesses, these depressions are cylindrically symmetrical.

We claim:

1. A magnet assembly for use in an apparatus for magnetic resonance spectroscopy, the magnet assembly comprising:
a superconducting magnet coil system for producing a magnetic field in a direction of a z-axis in a working volume disposed on the z-axis about z=0, wherein a field of said magnet coil system in the working volume has at least one inhomogeneous part Aₙ₀·zⁿ where n≧2, whose contribution to a total field strength on the z-axis about z=0 varies with an nth power of z; and
a field shaping device made from magnetic material, wherein at least part of said field shaping device has a radial distance from the z-axis of less than 80 millimeters and compensates for at least one of the inhomogeneous field parts Aₙ₀·zⁿ of said magnet coil system, wherein said field shaping device has one or more non cylindrically symmetric recesses which are constituted such that at least one coefficient Aₙₘ or Bₙₘ, where m≠0, is reduced in a magnetic field expansion of the magnet assembly according to spherical harmonic functions
$${B}_{z} ( r , z , ϕ ) = {\sum }_{n = 0}^{∞} {\sum }_{m = 0}^{n} {P}_{n}^{m} ( \frac{z}{\sqrt{{r}^{2} + {z}^{2}}} ) {( {r}^{2} + {z}^{2} )}^{n / 2} ( {A}_{nm} cos ( m ϕ ) + {B}_{nm} sin ( m ϕ ) )$$
by an amount of at least fifty percent.

2. The magnet assembly of claim 1, wherein said field shaping device comprises cooled components that, during operation, are preferably cooled to a temperature of a liquid-helium bath cooling said magnet coil system.

3. The magnet assembly of claim 1, wherein at least a part of said non cylindrically symmetric recesses has through-holes through said field shaping device.

4. The magnet assembly of claim 1, wherein at least a part of said non cylindrically symmetric recesses does not have through-holes through said field shaping device.

5. The magnet assembly of claim 4, wherein at least a part of said non cylindrically symmetric recesses is disposed on an inner side of said field shaping device.

6. The magnet assembly of claim 4, wherein at least a part of said non cylindrically symmetric recesses is disposed on an outer side of said field shaping device.

7. The method for producing the magnet assembly of claim 1, wherein at least a part of the non cylindrically symmetric recesses is cut by spark erosion.

8. The method for producing the magnet assembly of claim 1, wherein at least a part of the non cylindrically symmetric recesses is cut by a caustic substance.

9. A method for producing the magnet assembly of claim 1, wherein at least a part of the non cylindrically symmetric recesses is removed by electrolysis.

10. A method for producing the magnet assembly of claim 1, wherein at least a part of the non cylindrically symmetric recesses is removed by grinding or milling.

11. A method for producing the magnet assembly of claim 3, wherein the through-holes in the field shaping device are cut out with a laser beam.

12. A method for dimensioning the non cylindrically symmetric recesses in the magnet assembly of claim 1, wherein the coefficients Aₙₘ and Bₙₘ of the magnetic field expansion are determined according to the spherical harmonic functions by means of field measurement in or around the working volume in a magnet assembly with a field shaping device without non cylindrically symmetric recesses.
